(19) United States
(12) Patent Application Publication
(10) Pub. No.: US 2008/0237744 A1
(43) Pub. Date: Oct. 2, 2008

(54) Semiconductor Device and Manufacturing Method Thereof

(76) Inventor: EUN JONG SHIN, Mapo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/060,285

(22) Filed: Apr. 1, 2008

(30) Foreign Application Priority Data
Apr. 2, 2007 (KR) 10-2007-0032161

(51) Int. Cl. H01L 29/78; H01L 21/336

(52) U.S. Cl. 257/408; 438/287; 257/E21.437; 257/E29.266

(57) ABSTRACT

Provided is a semiconductor device and manufacturing method thereof. The semiconductor device includes a gate dielectric on a semiconductor substrate; and a gate electrode on the gate dielectric. The gate dielectric has a structure in which a buffer dielectric and a dielectric layer including a high-k material are stacked. The gate dielectric can be formed so as to reduce surface roughness between the gate dielectric and the semiconductor substrate and to improve the dielectric constant of the gate dielectric.

### CROSS-REFERENCE TO RELATED APPLICATION

The present application claims the benefit under 35 U.S.C. § 119 of Korean Patent Application No. 10-2007-0032161, filed Apr. 2, 2007, which is hereby incorporated by reference in its entirety.

### BACKGROUND

As the integration of semiconductor devices, particularly complementary metal oxide semiconductor (CMOS) devices, is accelerated, a gate and a gate dielectric material for resolving transistor performance deterioration and enhancing transistor performance are highly required.

A silicon oxide (SiO₂) layer formed by thermal oxidation is typically used as a gate oxide layer in a semiconductor device. However, as a semiconductor device becomes highly integrated, a thin gate oxide layer is required. At this point, when the SiO₂ layer having a too-thin thickness is used as the gate oxide layer, a leakage current by direct tunneling through the gate oxide layer increases, which results in an unstable device characteristic.

Therefore, recently, research for forming a gate dielectric using a high-k dielectric that can reduce an electric thickness while maintaining such a sufficient thickness as to prevent the direct tunneling is in progress.

FIGS. 1 to 3 illustrate a manufacturing process of a related art semiconductor device.

Referring to FIG. 3, a semiconductor substrate 10 has an active region defined by a device isolation layer (not shown). A gate stack is disposed on the active region, and has a structure where a silicon oxide layer 21, a high-k dielectric layer 31, and a gate electrode 41 are stacked. The high-k dielectric layer 31 includes Hafnium Oxide (HfO₂). Sidewalls 51 and spacers 61 are formed on the lateral sides of a gate electrode 41. Lightly doped drain (LDD) regions 71 and source/drain regions 81 are formed in the semiconductor substrate 10. Also, a silicide layer 91 is formed on the source/drain regions 81 and the gate electrode 41.

Here, the HfO₂ layer used as the gate dielectric material is formed using atomic layer deposition (ALD). A circle defect may be generated at the surface of the HfO₂ layer from a grain boundary or a pinhole depending on the number of ALD depositions. The circle defect has a dominant influence on the surface state of the semiconductor substrate 10 by increasing the leakage current characteristic of a device and deteriorating the driving current characteristic of the device.

To prevent these limitations, the number of times of ALD depositions is often increased to fifty times or more, or a dielectric is formed using a more uniform ALD through O₃ pre-treatment before an ALD process to improve adhesive characteristics as illustrated in FIGS. 1 and 2.

However, according to a gate forming process using the ALD, surface roughness is poor at the interface between the semiconductor substrate and a gate dielectric. Therefore, many defects exist at the contact surface. The defects in the contact surface serve as traps hindering movements of electrons or holes, deteriorating the operation performance of a transistor.

Also, in the case where the HfO₂ layer is deposited, a thick interface oxide layer is formed on the substrate to reduce the dielectric constant of the HfO₂ layer. However, this oxide layer increases a degree of crystallinity. Accordingly, when a predetermined electric field is applied, the electric field is locally concentrated and increases a leakage current.

### BRIEF SUMMARY

Embodiments of the present invention provide a semiconductor device that can reduce surface roughness between a gate dielectric and a semiconductor substrate by adopting a gate dielectric having a stacked structure of buffer dielectric layer and a high-k dielectric layer, and a manufacturing method thereof. The buffer dielectric layer can be a material capable of inhibiting an interface oxide layer from being generated during formation of the high-k dielectric layer. In many embodiments, the buffer dielectric layer is a silicon oxide nitride layer.

Embodiments also provide a semiconductor device that can improve the dielectric constant of a gate dielectric by forming a buffer dielectric and a high-k dielectric layer through implantation of N₂ ions into a semiconductor substrate, and a manufacturing method thereof.

Embodiments also provide a semiconductor device that can have a uniformly formed gate dielectric layer during an ALD process by forming a buffer dielectric and a high-k dielectric layer, and a manufacturing method thereof. According to an embodiment, the reliability of a device can be improved by inhibiting the occurrence of a grain boundary and pinholes through dangling bond compensation on the surface of a semiconductor substrate.

In one embodiment, a semiconductor device includes: a gate dielectric on a semiconductor substrate; and a gate electrode on the gate dielectric. The gate dielectric has a structure in which a buffer dielectric and a dielectric layer including a high-k material are stacked.

In another embodiment, a method for manufacturing a semiconductor device includes: forming a gate dielectric on a semiconductor substrate; and forming a gate electrode on the gate dielectric. The forming of the gate dielectric includes forming a buffer dielectric, and forming a dielectric layer formed of a high-k material on the buffer dielectric.

The details of one or more embodiments are set forth in the accompanying drawings and the description below. Other features will be apparent from the description and drawings, and from the claims.

### BRIEF DESCRIPTION OF THE DRAWINGS

FIGS. 1 to 3 are cross-sectional views illustrating a manufacturing process of a related art semiconductor device.

FIGS. 4 to 8 are cross-sectional views illustrating a manufacturing process of a semiconductor device according to an embodiment of the present invention.

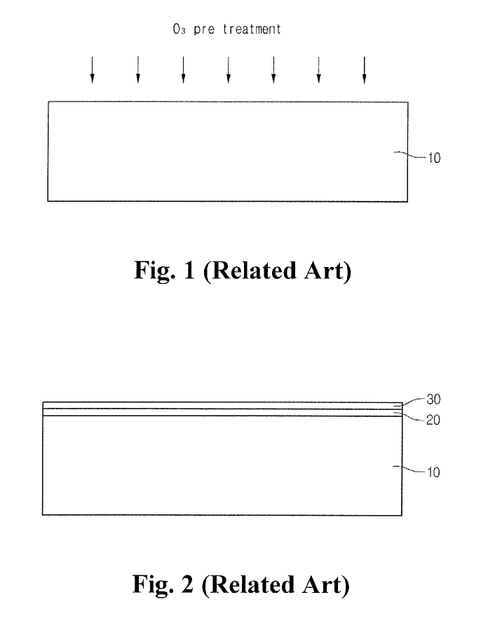

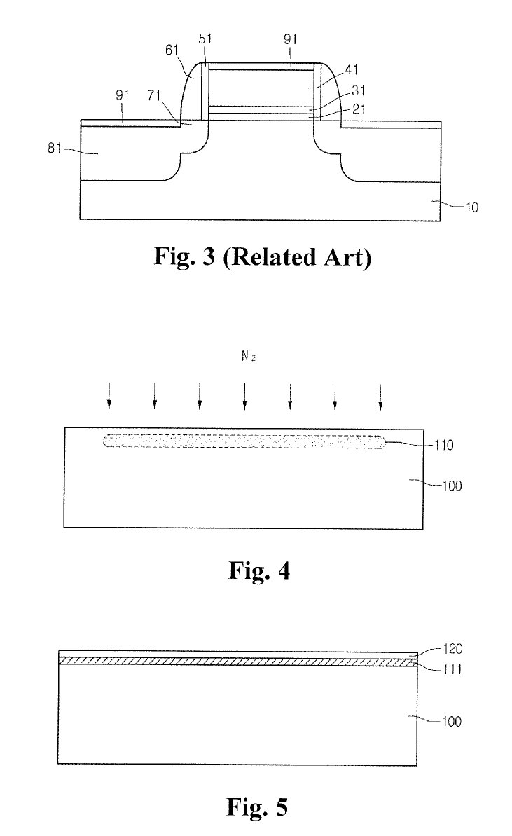

### DETAILED DESCRIPTION

Reference will now be made in detail to the embodiments of the present disclosure, examples of which are illustrated in the accompanying drawings.

In describing embodiments, it will be understood that when a layer (or film) is referred to as being ‘on’ or ‘over’ another layer or substrate, it can be directly ‘on’ or ‘over’ the another layer or substrate, or intervening layers may also be present.

In the drawings, the thickness or size of each layer is exaggerated, omitted, or schematically illustrated for convenience and clarity in description. Also, the size of each element does not totally reflect an actual size.

FIG. 7 is a cross-sectional view of a semiconductor device according to an embodiment.

Referring to FIG. 7, the semiconductor device can have a structure in which a gate dielectric 115 and a gate electrode 131 are stacked in the active region of a semiconductor substrate 100.

Sidewalls 141 and spacers 151 can be provided on the lateral sides of the gate dielectric 115 and the gate electrode 131. Lightly doped drain (LDD) regions 161 and source/drain regions 171 can be formed in the semiconductor substrate 100.

A nickel silicide layer 181 can be formed on the surface of the gate electrode 131 and the source/drain regions 171 to reduce contact resistance.

Also, according to one embodiment, the gate dielectric 115 can be formed in a structure in which a buffer dielectric 111 formed of a SiON and a dielectric layer 121 formed of HfO₂, which is a high-k material, are stacked.

According to an embodiment as illustrated in FIG. 8, the gate electrode 131 can be a gate electrode 191 formed of full silicide (FUSI) nickel.

A semiconductor device according to an embodiment has an effect of reducing surface roughness between the gate dielectric and the semiconductor substrate by adopting the gate dielectric having a stacked structure of the SiON layer and a high-k dielectric layer.

Also, since the SiON layer can be formed through implantation of N₂ ions into the semiconductor substrate and then the high-k dielectric layer is deposited thereon, a higher dielectric constant than that of the gate dielectric is realized. Accordingly, the dielectric constant of the gate dielectric improves and thus the electrical characteristic of a device improves.

The SiON can be formed on the semiconductor substrate through N₂ ion implantation and the high-k dielectric layer can be uniformly deposited through ALD, so that grain boundary and pinhole generation can be inhibited through dangling bond compensation and thus the reliability of a device can improve.

A method for manufacturing the semiconductor device according to an embodiment is described below with reference to FIGS. 4 to 8.

A semiconductor substrate 100 including a device isolation layer (not shown) and a well (not shown) can be provided.

Shallow trench isolation (STI) can be performed for the device isolation layer of the semiconductor substrate 100 to define an active region and a field region of a device.

Here, the semiconductor substrate 100 is generally a single crystal silicon substrate, and can be a substrate doped with P-type impurities or N-type impurities. According to certain embodiments, the device isolation layer (not shown) can be formed by forming a pad oxide layer and a mask layer exposing the field region on the semiconductor substrate 100, etching the exposed portion of the semiconductor substrate 100 to form a trench, filling the trench with silicon oxides, and removing the mask layer and the pad oxide layer.

Referring to FIG. 4, N₂ ions can be implanted into the active region of the semiconductor substrate 100 through ion implantation to form a SiN ion layer 110 in the semiconductor substrate 100.

Next, referring to FIG. 5, an annealing process can be performed on the semiconductor substrate 100 to activate the N₂ ions and form a buffer dielectric 111 of a SiON layer on the semiconductor substrate 100. The buffer dielectric 111 can improve the deposition uniformity of the gate dielectric 115 when a gate dielectric material is formed using ALD in a subsequent process. The buffer dielectric 111 can also improve an adhesive characteristic between the semiconductor substrate 100 and the gate dielectric 115 to relieve interface stress and compensate for local dangling bonds existing in the semiconductor substrate 100.

A dielectric layer 120 can be formed using ALD to form a gate dielectric 115 on the semiconductor substrate 100 on which the buffer dielectric 111 has been formed. According to one embodiment, the dielectric layer 120 can be formed by depositing a high-k material using ALD about 20-50 times. The high-k material can be HfO₂.

Deposition of a HfO₂ layer, which can be the dielectric layer 120, can be performed by depositing HfO₂ on the SiON layer, which can be the buffer dielectric 111. The HfO₂ layer is uniformly deposited on the semiconductor substrate 100 using the buffer dielectric 111, so that surface roughness of the interface reduces and grain boundary and pinhole generation are inhibited and thus the electrical characteristic of a device can be improved. Also, the buffer dielectric 111 formed on the semiconductor substrate 100 can inhibit an interface oxide layer from being generated during deposition of the HfO₂ layer to improve the dielectric constant of the HfO₂ layer.

Accordingly, the SiON layer can be formed between the semiconductor substrate 100 and the dielectric layer 120 to realize a high dielectric constant in the stack structure of the gate dielectric 115, so that the electrical characteristic of the semiconductor device can be multiplied.

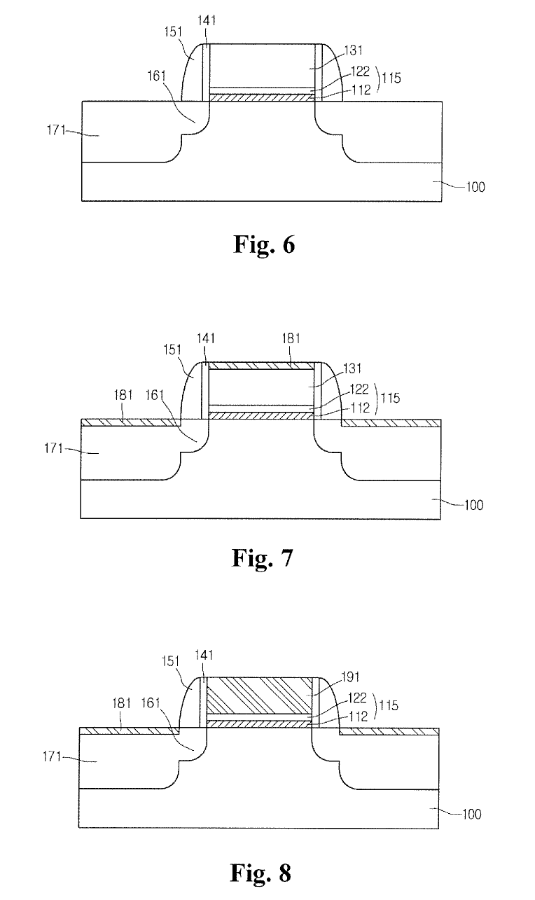

Next, referring to FIG. 6, polysilicon for forming a gate electrode 131 can be deposited on the semiconductor substrate 100 on which the buffer dielectric 111 and the dielectric layer 120 have been formed. A photoresist pattern (not shown) can be formed through a photolithography process, and an etching process can be performed to form the gate electrode 131 and a gate dielectric 115. The gate dielectric 115 can be formed from the buffer oxide layer 112 and the dielectric layer 122. The gate dielectric 115 has a high-k dielectric stack structure of Si—SiON—HfO₂ through the patterning process.

According to embodiments, the gate electrode 131 can be a layer of polysilicon or metal, or a stacked layer of polysilicon and metal. For high integration operation, a polysilicon gate is converted into a metal gate. According to one embodiment, in order to convert the polysilicon gate into a metal gate, germanium (Ge) ions (a group IV element) are implanted into the deposited polysilicon layer to change the polysilicon layer into an amorphous polysilicon layer, and then a silicide process is performed to convert the gate electrode 131 into a FUSI gate electrode 191 (described later).

According to an embodiment, an insulating layer such as an oxide layer can be formed through deposition on the substrate including the gate dielectric 115 and the gate electrode 131. Sidewalls 141 can be formed from the oxide layer through an etching process.

Low concentration impurities (N-type or P-type impurities) can be implanted into an exposed portion of the semiconductor substrate 100 using the gate electrode 131 as a mask to form low concentration regions used as LDD regions 161. In an embodiment, the sidewalls 141 and the gate electrode 131 can be used as the mask.

A dielectric can be deposited on the semiconductor substrate 100 on which the gate has been formed, and a blanket etching can be performed to form sidewall spacers 151 at the sides of the gate electrode 131 on which the sidewalls 141 have been formed.

High concentration impurities (N-type or P-type impurities) can be implanted using the gate electrode and the spacers 151 as a mask to form source/drain regions 171 connected to the LDD regions 161. Then, a heat treatment for activating dopants implanted into the source/drain regions 171 can be performed to form a junction region.

Next, referring to FIG. 7, a nickel (Ni) layer can be deposited and a primary heat treatment process can be performed to form a silicide layer on the gate electrode 131 and the source/drain regions 171. The Ni layer contacts the silicon at the lower portion to form a NiSi compound, so that a nickel silicide layer 181 is formed on the gate electrode 131 and the source/drain regions 171 to reduce contact resistance between a device and a line. In one embodiment, the primary heat treatment process can be performed at about 400° C. for about 30-35 seconds.

Also, portions of the Ni layer formed on regions excluding the nickel silicide layer 181 can be removed by performing a selective wet etching process.

Referring to FIG. 8, a secondary heat treatment process can be additionally performed on the nickel silicide layer 181 to convert the gate electrode 131 into a FUSI gate electrode 191. In one embodiment, the secondary heat treatment process is performed at about 450° C. for about 20-30 seconds.

As described above, according to certain embodiments, after polysilicon for forming the gate electrode 131 is deposited, Ge ions can be implanted to change the polysilicon layer into the amorphous polysilicon layer. Then, after the gate electrode 131 is formed, a primary heat treatment process can be performed when forming a nickel silicide layer 181, and a secondary heat treatment process can be performed to convert the gate electrode 131 into a nickel silicide, thus providing a FUSI gate electrode 191. Therefore, contact resistance between a device and a line can be reduced even more.

According to an embodiment, the semiconductor device and the manufacturing method thereof adopts a gate dielectric having a stacked structure of a SiON layer and a high-k dielectric layer such that the surface roughness between the gate dielectric and the semiconductor substrate can be reduced.

Also, according to an embodiment, N₂ ions can be implanted into the semiconductor substrate to form the SiON layer, and then the high-k dielectric layer is formed through deposition to realize the gate dielectric having a higher dielectric constant, so that the dielectric constant of the gate dielectric improves and thus the electric characteristic of a device can be improved.

Also, according to an embodiment, SiON can be formed on the semiconductor substrate through N₂ ion implantation and a high-k dielectric layer can be uniformly deposited through ALD, so that grain boundary and pinhole generation can be inhibited through dangling bond compensation and thus the reliability of a device can improve.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a gate dielectric on a semiconductor substrate; and
a gate electrode on the gate dielectric,
wherein the gate dielectric has a structure in which a buffer dielectric and a dielectric layer including a high-k material are stacked.

2. The semiconductor device according to claim 1, wherein the buffer dielectric comprises a SiON layer.

3. The semiconductor device according to claim 1, wherein the buffer dielectric comprises nitrogen.

4. The semiconductor device according to claim 1, wherein the buffer dielectric comprises a material capable of inhibiting an interface oxide layer from being generated during formation of the dielectric layer.

5. The semiconductor device according to claim 1, wherein the dielectric layer comprises a HfO₂ layer.

6. The semiconductor device according to claim 1, further comprising:
spacers on sidewalls of the gate dielectric and the gate electrode, and
lightly doped drain regions and source/drain regions in the semiconductor substrate.

7. The semiconductor device according to claim 6, further comprising a silicide on the gate electrode and the source/drain regions.

8. The semiconductor device according to claim 7, wherein the silicide comprises a nickel silicide.

9. The semiconductor device according to claim 1, wherein the gate electrode is a full silicide (FUSI) gate electrode.

10. A method for manufacturing a semiconductor device, comprising:
forming a gate dielectric on a semiconductor substrate by forming a buffer dielectric and forming a dielectric layer including a high-k material on the buffer dielectric; and
forming a gate electrode on the gate dielectric.

11. The method according to claim 10, wherein the forming of the buffer dielectric comprises:
implanting N₂ ions into the semiconductor substrate; and
performing an annealing process on the semiconductor substrate.

12. The method according to claim 10, wherein the forming of the buffer dielectric comprises forming a buffer layer capable of inhibiting an interface oxide layer from being generated during the forming of the dielectric layer.

13. The method according to claim 10, wherein the dielectric layer comprises a HfO₂ layer.

14. The method according to claim 10, wherein the forming of the dielectric layer comprises performing atomic layer deposition about 20-50 times.

15. The method according to claim 10, further comprising:
forming lightly doped drain regions in the semiconductor substrate using the gate electrode as a mask;
forming spacers on sidewalls of the gate electrode;
forming source/drain regions in the semiconductor substrate using the gate electrode and the spacers as a mask; and
forming a silicide on the gate electrode and the source/drain regions.

16. The method according to claim 15, further comprising:
forming insulating sidewalls on the gate electrode before forming the lightly doped drain regions, wherein the spacers contact the sidewalls on the sidewalls of the gate electrode.

17. The method according to claim 15, wherein the forming of the silicide comprises depositing nickel (Ni) on the semiconductor substrate and performing a primary annealing process.

18. The method according to claim 15, further comprising performing a secondary annealing process to convert the gate electrode into a full silicide gate electrode.

19. The method according to claim 10, wherein the forming of the gate electrode comprises:
forming a polysilicon layer on the gate dielectric through a deposition process;
implanting germanium (Ge) ions into the polysilicon layer to form an amorphous silicon layer; and
patterning the amorphous silicon layer to form the gate electrode.

20. The method according to claim 19, further comprising:
depositing Ni on the gate electrode and performing a primary annealing process to form a nickel silicide layer; and
performing a secondary annealing process to change the gate electrode into a full nickel silicide electrode.
